(19) United States
(12) Patent Application Publication
(10) Pub. No.: US 2004/0009436 A1
(43) Pub. Date: Jan. 15, 2004

(54) Methods for forming resist pattern and fabricating semiconductor device using Si-containing water-soluble polymer

(75) Inventors: Si-hyeung Lee, Suwon-city (KR); Jung-hyeon Lee, Suwon-city (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 10/391,342

(22) Filed: Mar. 18, 2003

(30) Foreign Application Priority Data
Jul. 9, 2002 (KR) 2002-39833

(51) Int. Cl. G03F 7/20; G03F 7/30; G03F 7/40; H01L 21/311

(52) U.S. Cl. 430/313; 430/330; 430/316; 430/317; 430/950; 438/703

(57) ABSTRACT

A Si-containing water-soluble polymer layer is formed on a resist pattern, and contacting portions of the resist pattern and the Si-containing water-soluble polymer layer are reacted to form Si-containing material layers. Thereafter, the portions of the Si-containing water-soluble polymer layer, which have not reacted with the resist pattern, are removed using deionized water so that Si-containing material layers encompassing the resist pattern remain. Since such Si-containing material layers improve the etching resistance and the thickness of the resist pattern, the semiconductor material having a step difference can be etched. In addition, a CD of the adjacent resist pattern can be increased. Furthermore, since an etching resistance against an electron-beam improves, the shrinkage of the CD when measuring the CD using an in-line scanning electron microscope (ILS) is prevented so that the CD can be maintained.

This application claims priority to Korean Patent Application No. 2002-39833, filed Jul. 9, 2002 in the Korean Intellectual Property Office, which is incorporated by reference herein in its entirety.

### BACKGROUND OF THE INVENTION

1. Field of the Invention

The present invention relates to a method for fabricating a semiconductor device, and more particularly, to a method for forming a resist pattern and a method for fabricating a semiconductor device using the same.

2. Description of the Related Art

As semiconductor devices become more highly integrated, interconnections and separation widths needed in the fabrication of the semiconductor devices decrease. In general, fine line patterns are etched into a substrate using a lithographic process, wherein a resist pattern is used as a mask.

Accordingly, lithographic techniques are important in the process of forming the fine line patterns. In a conventional method, a resist is patterned by exposure to light, e.g., KrF (248 nm) or ArF (193 nm). The resist develops at different rates depending on a wavelength of the light such that a desired photoresist pattern is achieved. In addition, the desired pattern is transferred to a lower layer using the difference between the etching selectivity of the photoresist and the etching selectivity of the lower layer.

When the thickness of the lower layer to be etched is uneven due to a step difference or the amount of the lower layer to be etched is uneven due to the step difference on a wafer and open ratios, the thickness of the photoresist needs to be increased. However, thicker photoresists have reduced resolution and depth of focus (DOF) and result in the collapsing of the patterns due to an increase in an aspect ratio. Thus, the conventional lithography techniques using photoresists can compromise a profile of a material layer pattern. In particular, the transmittance of ArF or F₂ (157 nm) resists is only about 50 to 60% of the transmittance of the KrF resist. Accordingly, ArF or F₂ resists exhibit a slope profile having a thickness larger than 3,000 Å.

One proposed solution is a thin resist having a high etching resistance; however, it is difficult to improve the etching resistance of the resist. In particular, the etching rate of the ArF or F₂ resist is about 30% greater than the etching rate of the KrF resist. Accordingly, it is difficult to control the etching resistance of the resists with conventional methods.

For technologies such as gate electrodes, a maximum critical dimension (CD) is needed at a specific pitch. One difficulty in manufacturing these devices is that as CD increases, bridges occur due to the limited resolution. Accordingly, techniques for decreasing the thickness of the resist, using equipment having a high numerical aperture, and enhancing resolution are introduced in the fabrication process. As a result, costs increase and the processes become more complicated.

In particular, the ArF or F₂ resist has a low resistance against an electron-beam compared to the KrF resist. Therefore, the ArF or F₂ resist exhibits shrinkage when measuring the CD using an in-line scanning electron microscope (ILS) after a sample photo process, thereby decreasing the CD. Accordingly, in the case of the ArF or F₂ resist, although the profile for the photo process can be secured, it is difficult to perform an etching process due to the small thickness and the low resistance of the resist. Studies for improving the hard mask, etching resistance, transmittance, and electron-beam resistance of the ArF resist have taken place; however, the results are not significant.

### SUMMARY OF THE INVENTION

To solve the above-described problems, it is an objective of the present invention to provide a method for forming a resist pattern using an existing resist to improve an etching resistance and a method for fabricating a semiconductor device using the same.

It is another objective of the present invention to provide a method for forming a resist pattern to attain an improved critical dimension (CD) at a specific pitch without using additional equipment and a method for fabricating a semiconductor device using the same.

According to an embodiment of the present invention, a resist pattern is formed and a Si-containing water-soluble polymer is blanket coated on the resist pattern. When an exposure process and/or a baking process is performed, a crosslinking reaction takes place at the boundaries between the resist pattern and the Si-containing water-soluble polymer. Accordingly, when performing a washing process using deionized water, the Si-containing water-soluble polymer is washed out; however, the portions of the Si-containing water-soluble polymer that have crosslinking reacted with the resist pattern remain as substantially uniform layers encompassing the resist pattern. Here, the crosslinking reaction denotes, for example, a state of linking the resist pattern and the Si-containing water-soluble polymer by acid, which is generated from the resist pattern.

The etching resistance of specific portions of the resist pattern is improved so that the photoresist having a small thickness compensates for the reduction of depth of focus (DOF) due to a step difference. In addition, the above-described processes are performed after a possible CD target is formed to improve the CD of the resist pattern. Furthermore, since the etching resistance of the resist pattern against an electron-beam is improved, the shrinkage of the resist pattern when measuring the CD using an in-line scanning electron microscope (ILS) is prevented so that the uniform CD is maintained.

### BRIEF DESCRIPTION OF THE DRAWINGS

The above objectives and advantages of the present invention will become more apparent by describing in detail preferred embodiments thereof with reference to the attached drawings in which:

FIGS. 1 through 5 are sectional views explaining a method for fabricating a semiconductor device by etching a semiconductor material having step difference according to a first embodiment of the present invention;

FIGS. 6 through 9 are sectional views explaining a method for fabricating a semiconductor device by etching a semiconductor material having step difference according to a second embodiment of the present invention;

FIGS. 10 through 13 are sectional views explaining a method for fabricating a semiconductor device by securing a critical dimension (CD) as high as possible at a specific pitch according to a third embodiment of the present invention; and

FIGS. 14 through 16 are sectional views explaining a method for fabricating a semiconductor device according to a fourth embodiment of the present invention.

### DETAILED DESCRIPTION OF PREFERRED EMBODIMENTS

The present invention will now be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and regions are exaggerated for clarity. The same reference numerals in different drawings represent the same element.

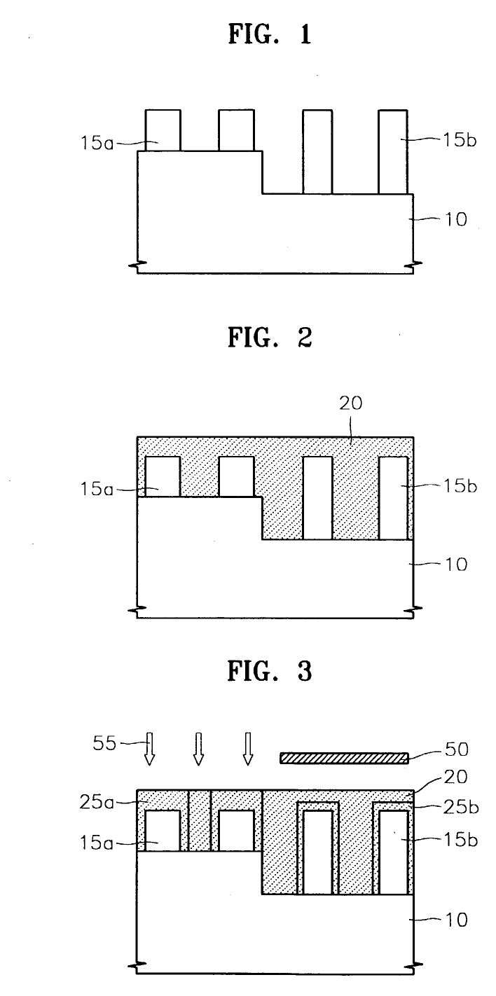

FIGS. 1 through 5 are sectional views explaining a method for fabricating a semiconductor device according to an embodiment of the present invention, wherein a layer to be etched has various thicknesses due to a step difference of a semiconductor material 10 as shown in FIG. 1. The semiconductor material 10 maybe a semiconductor substrate, an insulating layer such as a silicon oxide layer formed on the semiconductor substrate, or a conductive layer such as an impurity doped polysilicon layer. Accordingly, the present invention can be applied to any semiconductor material upon which a resist pattern can be formed.

Referring to FIG. 1, a KrF, ArF, or F₂ resist is coated onto a semiconductor material 10 having a small step difference, for example, a thickness of 3,000 Å, to secure resolution and depth of focus (DOF). Here, the resist is coated onto the hexamethyldisilazane (HMDS) processed semiconductor material 10 using a spin coating process at about 3,000 rpm. A pre-baking process is performed on the resist at a temperature of 120° C. for 90 seconds to evaporate a solvent from the resist.

The coated resist is exposed and developed using a predetermined mask to form resist patterns 15a and 15b. Here, the resist is exposed using a light source corresponding to the peak wavelength of the coated resist. When needed, the resist is post-baked at a temperature of 120° C. for about 90 seconds to improve the resolution of the resist. Thereafter, the resist is developed using a development solution, such as tetramethylammonium hydroxide (TMAH) solution, for about 60 seconds. Since the semiconductor material 10 has step difference, the thin pattern 15a is formed on the portion of the semiconductor material 10 having a thickness larger than the portion of the semiconductor material 10 upon which pattern 15b is formed.

Referring to FIG. 2, a Si-containing water-soluble polymer layer 20 is blank coated on the resultant structure of FIG. 1. Here, the Si-containing water-soluble polymer layer 20 may be coated by a spray method, a rotation method, or an immersion method to form a uniform layer. When the rotation method is used, a rotation speed is about 2,000 rpm. The Si-containing water-soluble polymer layer 20 is formed of a polymer, which will be dissolved by deionized water in a subsequent development process while not dissolving the resist patterns 15a and 15b. In the case where a crosslinking reaction does not take place, the Si-containing water-soluble polymer can be mixed with an water-soluble crosslinking agent. The Si-containing water-soluble polymer may be mixed with other components in a proper solvent and applied in a resist type. Here, the resist including the Si-containing water-soluble polymer may be affected by the composition of resist materials. Thus, it is preferable that the resist composition is optimized. Here, the kinds and the composition ratio of the Si-containing water-soluble polymer are not limited so that it is preferable that the optimum Si-containing water-soluble polymer is used. An exemplary structure of the Si-containing water-soluble polymer and a manufacturing method thereof will be described later.

Referring to FIG. 3, the Si-containing water-soluble polymer layer 20 is exposed to light 55 from a light source using a mask 50 having an opening at a desired portion and baked to selectively enhance an etching resistance of the resist patterns 15a and 15b. The light 55 has a wavelength in the peak wavelength of the resist can be used for the exposure process. Accordingly, acid is generated from the exposed resist pattern 15a to form crosslinking layers, which encompass the resist pattern 15a, due to a crosslinking reaction at the boundaries between the Si-containing water-soluble polymer and the resist pattern 15a. Here, the crosslinking layers are referred to as Si-containing material layers 25a. The exposure process generates acid to start the crosslinking reaction, and the subsequent baking process supplies heat energy to activate the crosslinking reaction. If the baking process is continuously performed, the thickness of the Si-containing material layers 25a is increased. If a baking temperature is increased to generate a large amount of acid from the resist patterns 15a and 15b, Si-containing material layers 25b encompassing the unexposed resist pattern 15b can be formed. However, by controlling the baking temperature, only the Si-containing material layers 25a can be formed around the exposed resist pattern 15a. When needed, the resist including the Si-containing water-soluble polymer may contain a photo acid generator. The thickness of the Si-containing material layers 25a formed around the thin resist pattern 15a on the thick portion of the semiconductor material 10 is greater than the thickness of the Si-containing material layers 25b formed around the thick resist pattern 15b on the thin portion of the semiconductor material 10.

The exposure process is performed using the mask 50; however, the exposure process can be performed without the mask 50. Both the exposure process and the baking process are performed; however, only one of the exposure process and the baking process is needed to change the composition of the resist including the Si-containing water-soluble polymer. When the baking process is performed alone, the baking process is performed at a temperature of about 150° C. for 90 seconds.

The crosslinking reaction is controlled by the reactivity of the resist pattern and the Si-containing water-soluble polymer, the shape and the thickness of the resist pattern, the needed thickness of the crosslinking layers, i.e., the Si-containing material layers, the exposure condition, and the coating condition.

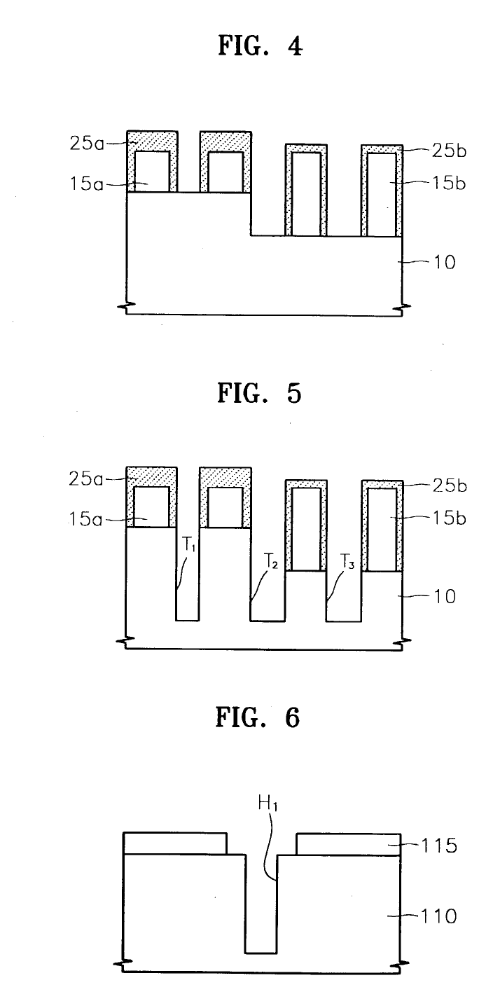

Thereafter, a development process is performed using deionized water. Accordingly, the Si-containing water-soluble polymer is dissolved; however, the portions of the Si-containing water-soluble polymer, which have crosslinking reacted with the resist patterns 15a and 15b, i.e., the Si-containing material layers 25a and 25b, are not dissolved, as shown in FIG. 4. Thus, the Si-containing material layers 25a and 25b encompass the resist patterns 15a and 15b to a substantially uniform thickness.

More specifically, the baked Si-containing water-soluble polymer layer 20 is developed for about 60 seconds using the deionized water. Here, the portions of the Si-containing water-soluble polymer layer 20 contacting the resist patterns 15a and 15b remain due to the crosslinking reaction. These crosslinked portions encompass the resist patterns 15a and 15b and form the Si-containing material layers 25a and 25b. The crosslinking reaction does not occur on the portions of the Si-containing water-soluble polymer layer 20 contacting the semiconductor material 10 while not contacting the resist patterns 15a and 15b and are thus washed out by the deionized water. Therefore, since the Si-containing material layers 25a and 25b, as hard layers, have an excellent etching resistance, the etching resistance of the resist patterns 15a and 15b is substantially improved due to the encompassing Si-containing material layers 25a and 25b. The resist patterns 15a and 15b are protected by the Si-containing material layers 25a and 25b and remain after the etching process of the semiconductor material 10 so that a stable etching process can be performed.

Referring to FIG. 5, when the semiconductor material 10 is etched using the resist patterns 15a and 15b having the improved etching resistance to form trenches T₁, T₂, and T₃ having different depths, the problem of the narrow DOF margin due to the step difference can be alleviated.

FIGS. 6 through 9 are sectional views explaining a method for fabricating a semiconductor device according to another embodiment of the present invention. A contact hole H₁ having a high aspect ratio is formed in a semiconductor material 110 as shown in FIG. 6. A resist pattern having a small thickness is formed on the semiconductor material 110. The resist pattern 115 is coated with a Si-containing water-soluble polymer layer 120. A crosslinking reaction between the resist pattern 115 and the Si-containing water-soluble polymer layer 120 occurs. Thus, an etching resistance is selectively enhanced to form a desired structure.

Referring to FIG. 6, a resist is coated onto the semiconductor material 110 to a thickness of about 3,00 Å to secure a desired resolution and DOF. Here, the semiconductor material 110 includes the contact hole H₁ having a high aspect ratio. Thereafter, the resist is exposed and developed to form a resist pattern 115 around the contact hole H₁.

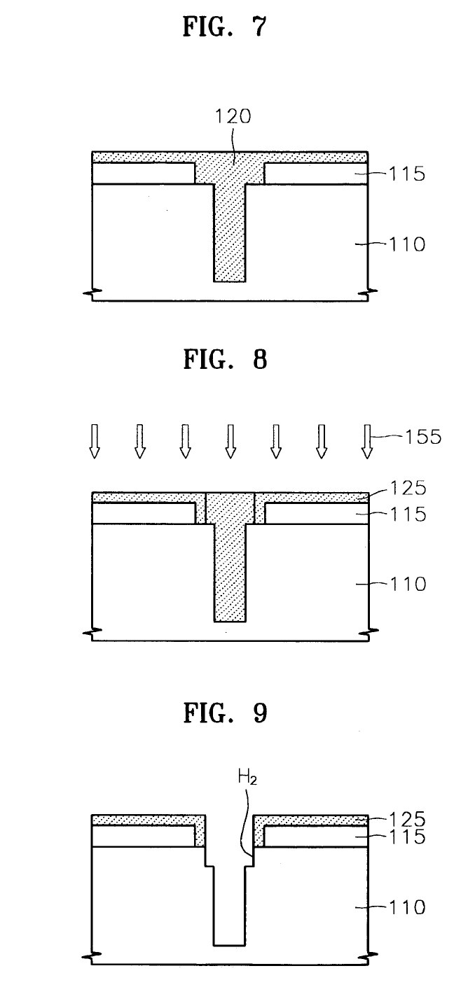

Referring to FIG. 7, the Si-containing water-soluble polymer layer 120 is coated on the resultant structure of FIG. 6. Here, the Si-containing water-soluble polymer layer 120 is spin coated at a speed of about 2,000 rpm.

Referring to FIG. 8, the resultant structure of FIG. 7 is exposed to light 155 from a light source and baked. More specifically, the resultant structure having the Si-containing water-soluble polymer layer 120 is exposed. The exposure process is performed without using a mask; however, in some cases the exposure process may be performed using a mask having openings at desired portions. Thereafter, the exposed Si-containing water-soluble polymer layer 120 is baked at a temperature of 90 to 120° C. for 30 to 150 seconds. The exposure process generates acid from the resist pattern 115, and the acid is activated by heat energy of the baking process so that a crosslinking reaction between the resist pattern 115 and the Si-containing water-soluble polymer 120 occurs. Accordingly, Si-containing material layers 125 encompassing the resist pattern 115 are formed.

Referring to FIG. 9, the Si-containing water-soluble polymer 120 is dissolved by deionized water; however, the portions of the Si-containing water-soluble polymer 120 that have reacted with the resist pattern 115, i.e., the Si-containing material layers 125, are not washed out. Thus, the Si-containing material layers 125 as substantially uniform layers encompass the resist pattern 115. Thus, the etching resistance of the resist pattern 115 is substantially improved due to the Si-containing material layers 125, which encompass the resist pattern 115. When a contact hole H₂ is formed by etching the semiconductor material 110 while using the resist pattern 115 having the improved etching resistance as an etch mask, the problem of a narrow DOF margin due to step difference can be alleviated.

When the method according to the present embodiment is used, a dual damascene process in a highly integrated device can be efficiently performed.

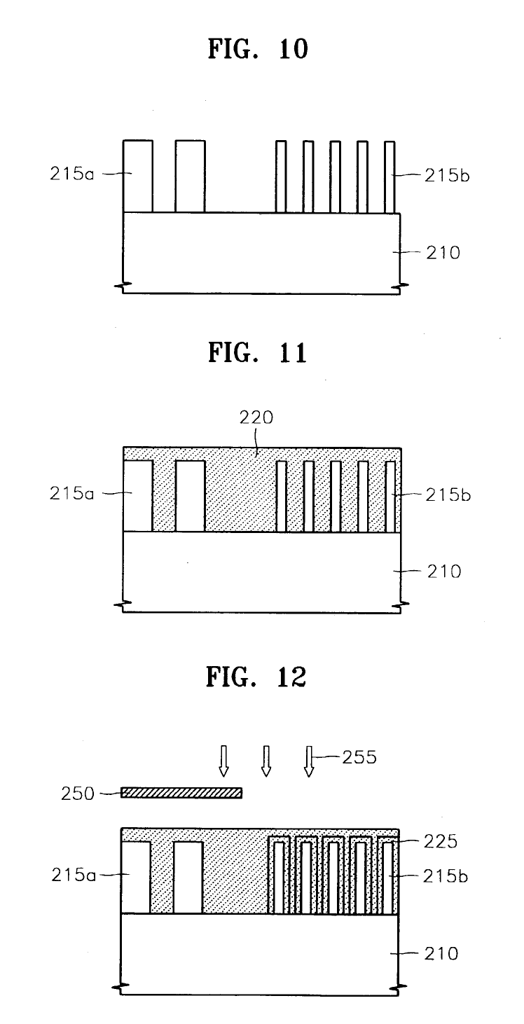

FIGS. 10 through 13 are sectional views explaining a method for fabricating a semiconductor device according to an embodiment of the present invention.

For CD's that need to be as high as possible at a specific pitch in a lithography process, it is difficult to obtain a high CD after development inspection (ADI), compared to a low CD. Although the increase in the CD of gate electrodes is desired, the increase in the CD may cause bridges due to the limitation in the resolution of a resist. According to an embodiment of the present invention, the possible resolution is defined in the ADI as shown in FIG. 10 and the CD is increased according to the scheme shown in FIGS. 11 through 13.

Referring to FIG. 10, line-typed resist patterns 215a and 215b are formed on a semiconductor material 210. Accordingly, a possible resolution is defined in the ADI.

Thereafter, referring to FIG. 11, a Si-containing water-soluble polymer layer 220 is deposited on the resultant structure of FIG. 10. Here, the Si-containing water-soluble polymer layer 220 is coated by a spin coating method at a speed of about 2,000 rpm.

Referring to FIG. 12, the Si-containing water-soluble polymer layer 220 is exposed to light 255 from a light source using a mask 250 having openings at portions for increasing the CD, for example, cell portions in the case where the cell CD is desired to be increased. The exposed Si-containing water-soluble polymer layer 220 is baked at a temperature of 90 to 120° C. for 30 to 150 seconds. The exposure process generates acid from the resist pattern 215b, and heat energy of the baking process activates acid so that the resist pattern 215b reacts with the Si-containing water-soluble polymer 220 to form crosslinking layers encompassing the resist pattern 215b, i.e., Si-containing material layers 225. The generation of acid and the crosslinking reaction depend on a dose amount of the exposure process and a temperature of the baking process. Accordingly, the dose amount and the temperature need to be controlled to obtain crosslinking layers of a desired thickness. In particular, it is important to control the temperature of the baking process to activate the crosslinking reaction only around the exposed resist pattern 215b.

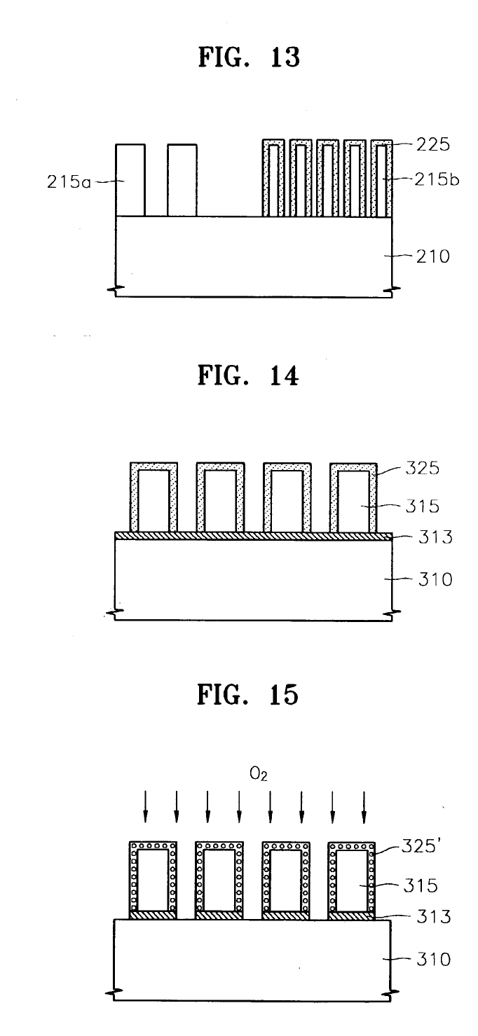

Referring to FIG. 13, deionized water is supplied to the resultant structure of FIG. 12. Accordingly, the Si-containing water-soluble polymer 220 is washed out; however, the portions of the Si-containing water-soluble polymer 220 that have reacted with the resist pattern 215b, i.e., the Si-containing material layers 225, are not washed out. Here, the Si-containing material layers 225, as substantially uniform layers, encompass the resist pattern 215b. Thus, the thickness of the resist pattern 215b is increased and the CD of the resist pattern 215b is increased. Here, as described above, the CD of the resist pattern 215b can be adjusted by controlling the dose amount of the exposure process and the temperature of the baking process.

When the semiconductor material 210 is etched using such resist pattern 215b, the high CD can be attained at a specific pitch.

FIGS. 14 through 16 are sectional views explaining a semiconductor device according to yet another embodiment of the present invention.

Referring to FIG. 14, an organic anti-reflection coating (ARC) 313 is formed on a semiconductor material 310 to a thickness of about 300 Å to prevent the deformation of a resist pattern due to light, which is reflected in a horizontal direction. Thereafter, a KrF, ArF, or F₂ resist is coated onto the ARC, for example, to a thickness of 3,000 Å, to secure resolution and DOF. The resist is exposed and developed using a predetermined mask in order to form a resist pattern 315 having a CD of 100 nm. A Si-containing water-soluble polymer layer is coated onto the resultant structure by a spray method, a rotation method, or an immersion method. Thereafter, the Si-containing water-soluble polymer layer is baked at a temperature of 150° C. for 90 seconds and developed using deionized water for 60 seconds. The baking process generates acid from the resist pattern 315, and a crosslinking reaction occurs at the boundaries between the Si-containing water-soluble polymer and the resist pattern 315 so that crosslinking layers i.e., Si-containing material layers 325, are formed encompassing the resist pattern 315.

Referring to FIG. 15, the organic ARC 313 is etched using oxygen plasma for 60 seconds before the semiconductor material 310 is etched using the resist pattern 315 as an etch mask. The Si-containing material layers 325 are silylated by the oxygen plasma and resulting in SiOx. Since SiOx layers 325′ have an improved etching resistance, the SiOx layers 325′ can be used as a hard mask when etching the semiconductor material 310.

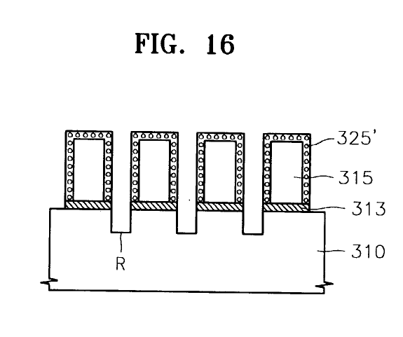

Referring to FIG. 16, the semiconductor material 310 is etched using the resist pattern 315, which is encompassed by the SiOx layers 325′, as an etch mask so that desired recesses R are obtained.

As described above, since the ArF or F₂ resist has a low resistance against an electron-beam compared to the KrF resist, the CD is decreased due to shrinkage when measuring the CD using an in-line scanning electron microscope (ILS) after an actual sample photo process is performed. However, if the resistance against the electron-beam is improved as in the present embodiment, the CD is maintained even after a specific amount of time has passed.

According to an embodiment of the present invention, the crosslinking layers are formed on the resist pattern on a selected region of the semiconductor material and the crosslinking layers are not formed on the resist pattern on the other regions. Accordingly, a region of the semiconductor material can be selectively exposed using a proper mask, the exposed region and the unexposed region can be separated, and only the selected portions of the resist pattern react with the Si-containing water-soluble polymer. As a result, it is possible to form the resist patterns having different etching resistances and/or CDs on the same semiconductor material.

An exemplary structure of a Si-containing water-soluble polymer and a method for manufacturing the same used in the embodiments of the present invention will now be described.

2.58 g of 0.03 mol methacrylic acid (MAA), 3.43 g of 0.03 mol 2-hydroxyethyl methacrylate (HEMA), and 13.31 g of 0.04 mol methacryl oxypropyl trimethoxy silane (MPTS) are mixed with 19.3 g of dried ethyl acetate, and 1.64 g of 10 mol % azobisisobutyronitrile (AIBN), which is refined in methanol, is added to a mixture. The mixture is agitated to completely dissolve AIBN and purged using nitrogen gas (N₂). The mixture is frozen using liquid N₂ and slowly dissolved under a decompression condition to completely remove oxygen from the reaction mixture. The above-processes are repeated twice. Thereafter, the mixture is polymerized in an oil bath, which maintains a temperature of 65° C., for 24 hours. The polymerized mixture is dissolved in 50 g of anhydrous tetrahydrofuran (THF) and slowly dropped into a solvent, which is formed by mixing n-hexane and isopropyl alcohol (IPA) at a ratio of 3:1, to be precipitated. The precipitated white solid is filtered and dissolved in THF again. The above-processes are repeated three times. Thereafter, the mixture is filtered and dried in a vacuum oven at a temperature of 50° C., to obtain a polymer shown in FIG. 7, with an yield of 83%.

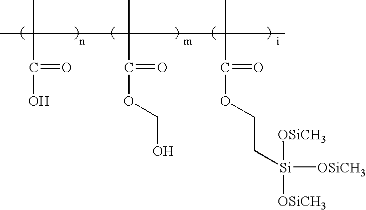

Thereafter, 3 g of the polymer (MM-HEMA-MPTS) and 0.3 g of hexamethoxymethylmelanin (HMMM) are dissolved in 10 g of polypropylene glycol methyl ethyl acetate (PGMEA) to prepare the Si-containing water-soluble polymer. When needed, the Si-containing water-soluble polymer can be mixed with a water-soluble crosslinking agent. The weight average molecular weight of the Si-containing water-soluble polymer is about 3,000 to about 50,000 daltons

As described above, the crosslinking layers are formed on select portions of the resist pattern. Accordingly, the portions of the resist pattern formed on the semiconductor material can be selectively exposed using a proper mask, the exposed region and the unexposed region can be separated, and only the selected portions of the resist pattern react with the Si-containing water-soluble polymer.

Since the crosslinking layers are the Si-containing material layers, the etching resistance of the resist pattern is improved due to the crosslinking layers. Accordingly, it is sufficient to coat the resist to a thickness such that the DOF can be secured and the collapsing of the resist pattern can be prevented. In addition, an excellent etching profile can be obtained.

Furthermore, patterns having different CDs can be formed on the same semiconductor material. In this case, if the possible resolution is defined in the ADI and the crosslinking reaction is generated, the CD can be easily increased.

In particular, even when the pattern is formed using the ArF or F₂ resist whose CD is decreased by shrinkage when measuring the CD using the ILS after the sample photo process due to the low etching resistance against the electron-beam compared to the KrF resist, the CD can be maintained by improving the etching resistance according to an embodiment of the present invention.

Therefore, the present invention stabilizes the processes for fabricating the semiconductor to increase the integration of the semiconductor device while increasing the process tolerance of the semiconductor device to improve yield and reliability of the operation of the semiconductor device.

While this invention has been particularly shown and described with reference to preferred embodiments thereof, it will be understood by those skilled in the art that various changes in form and details may be made therein without departing from the spirit and scope of the invention as defined by the appended claims. For example, the exposure process and/or the baking process is performed to generate acid from the resist patterns in order to generate the crosslinking reaction between the resist pattern and the Si-containing water-soluble polymer in the present embodiments. However, the crosslinking reaction between the resist pattern and the Si-containing water-soluble polymer can be induced without generating acid from the lower resist pattern by controlling the composition of the resist including the Si-containing water-soluble polymer. Therefore, the scope of the invention is defined by the appended claims.

What is claimed is:

1. A method for fabricating a semiconductor device, the method comprising:
(a) forming a resist pattern on a semiconductor material;
(b) forming a Si-containing water-soluble polymer layer for covering the semiconductor material including the resist pattern;
(c) performing a crosslinking reaction between contacting portions of the resist pattern and the Si-containing water-soluble polymer layer to form Si-containing material layers on the surfaces of the resist pattern;
(d) removing non-reacted portions of the Si-containing water-soluble polymer layer using deionized water; and
(e) etching the semiconductor material using the resist pattern as an etch mask.

2. The method of claim 1, wherein the crosslinking reaction for forming the Si-containing material layers is generated by one of exposing, baking, or exposing and baking the semiconductor material including the Si-containing water-soluble polymer layers.

3. The method of claim 2, wherein the exposing is selectively performed on desired portions of the Si-containing water-soluble polymer-layer.

4. The method of claim 2, wherein the thickness of the Si-containing material layers is controlled by a dose amount of the exposing, a temperature of the baking, or the combination of the dose amount and the temperature.

5. The method of claim 1, wherein the semiconductor material has a step difference, and wherein the resist pattern is formed of a plurality of resist pattern portions having different thicknesses according to the step difference, wherein upper surface of the resist pattern is level.

6. The method of claim 5, wherein the crosslinking reaction for forming the Si-containing material layers is selectively performed on a first portion of the resist pattern having a smaller thickness relative to a second portion of the resist patterns.

7. The method of claim 6, wherein exposing and baking are selectively performed on the first portion of the resist pattern.

8. The method of claim 1, wherein the resist is a KrF, ArF, or F₂ resist.

9. The method of claim 1, further comprising:
forming an organic anti-reflection coating (ARC) on the semiconductor material, before step (a); and
silylating the Si-containing material layers by etching the organic ARC using oxygen plasma, before step (e).

10. The method of claim 1, wherein the Si-containing water-soluble polymer layer is formed using polymers represented by following structural formula, 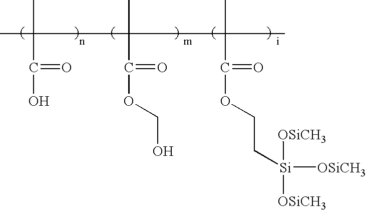
wherein l/(l+m+n)=0.1 to 0.4, m/(l+m+n)=0.1 to 0.5, and n/(l+m+n)=0.1 to 0.4.

11. The method of claim 10, wherein the weight average molecular weight of the Si-containing water-soluble polymer is about 3,000 to about 50,000 daltons.

12. The method of claim 1, wherein the Si-containing water-soluble polymer is mixed with a crosslinking agent, which induces the crosslinking reaction using acid diffusion.

13. A method for fabricating a semiconductor device to selectively improve an etching resistance of a resist and to increase a critical dimension (CD), the method comprising:
(a) forming a resist pattern having a first width on a semiconductor material;
(b) forming a Si-containing water-soluble polymer layer for covering the semiconductor material including the resist pattern;
(c) forming Si-containing material layers by performing a crosslinking reaction between contacting portions of the resist pattern and the Si-containing water-soluble polymer layer by exposing, baking, or exposing and baking the semiconductor material including the Si-containing water-soluble polymer layer;
(d) removing non-reacted portions of the Si-containing water-soluble polymer layer using deionized water; and
(e) etching the semiconductor material using a resist pattern, which has an increased second width due to the Si-containing material layers, as an etch mask.

14. The method of claim 13, wherein the thickness of the Si-containing material layers is controlled by a dose amount of the exposing, a temperature of the baking, or the combination of the dose amount and the temperature.

15. The method of claim 13, wherein the resist is a KrF, ArF, or F₂ resist.

16. The method of claim 13, wherein the exposing is selectively performed on portions of the Si-containing water-soluble polymer layer for improving an etching resistance or increasing CD of the resist pattern.

17. The method of claim 13, further comprising:
forming an organic ARC on the semiconductor material, before step (a); and
silylating the Si-containing material layers by etching the organic ARC using oxygen plasma, before step (e).

18. The method of claim 13, wherein the Si-containing water-soluble polymer layer is formed using polymers represented by following structural formula, 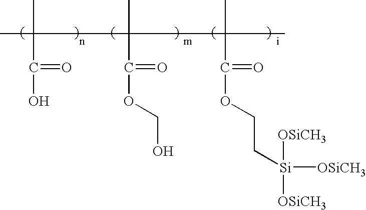
wherein l/(l+m+n)=0.1 to 0.4, m/(l+m+n)=0.1 to 0.5, and n/(l+m+n)=0.1 to 0.4.

19. The method of claim 18, wherein the weight average molecular weight of the Si-containing water-soluble polymer is about 3,000 to about 50,000 daltons.

20. The method of claim 13, wherein the Si-containing water-soluble polymer is mixed with a crosslinking agent, which induces the crosslinking reaction using acid diffusion.
